(19) United States
(12) Patent Application Publication
(10) Pub. No.: US 2011/0221488 A1
(43) Pub. Date: Sep. 15, 2011

(54) INTERFACE CIRCUIT WITH DAMPING RESISTOR CIRCUIT

(75) Inventors: Hideki Sasaki, Kanagawa (JP); Akinori Sakurai, Kanagawa (JP); Masayoshi Hirata, Kanagawa (JP)

(73) Assignee: RENESAS ELECTRONICS COPRORATION

(21) Appl. No.: 13/044,336

(22) Filed: Mar. 9, 2011

(30) Foreign Application Priority Data
Mar. 11, 2010 (JP) 2010-054196

(51) Int. Cl. H03L 7/06; H03L 7/00

(52) U.S. Cl. 327/155; 327/161

(57) ABSTRACT

A semiconductor integrated circuit is provided with: a variable resistor section, a variable delay section and a data fetch section. The variable resistor section provides damping for a data signal inputted thereto to thereby generate a damped data signal. The damping resistance of the damping is variable. The variable delay section gives a variable delay to a clock signal to thereby generate a delayed clock signal. The data fetch section fetches data from the damped data signal in synchronization with the delayed clock signal.

### INCORPORATION BY REFERENCE

This application claims the benefit of priority based on Japanese Patent Application No. 2010-054196, filed on Mar. 11, 2010, the disclosure of which is incorporated herein by reference.

### BACKGROUND OF THE INVENTION

1. Field of the Invention

The present invention relates to a semiconductor integrated circuit and an interface circuit.

2. Description of the Related Art

Japanese Patent Application Publication No. P2001-344041 A discloses a clock supply method for supplying a clock signal generated by an oscillator to a clock terminal of a data latch via a damping resistor in order to latch data inputted to a data input terminal of the data latch. In this method, a plurality of phase-advanced clock signals are generated, which have phases advanced from the clock signal generated by the oscillator, and an optimal clock signal is selected from the phase-advanced clock signals and outputted to the damping resistor. That is, when a damping resistor is inserted as a measure against EMI (electro-magnetic interference), a delay is generated due to the damping resistor. In this technique, the delay is adjusted in an output circuit.

### SUMMARY

In an aspect of the present invention, a semiconductor integrated circuit is provided with: a variable resistor section providing damping to a data signal inputted thereto to thereby generate a damped data signal, wherein a damping resistance of the damping is variable; a variable delay section giving a variable delay to a clock signal to thereby generate a delayed clock signal; and a data fetch section fetching data from the damped data signal in synchronization with the delayed clock signal.

In another aspect of the present invention, an interface circuit is provided with: a variable resistor section providing damping to a data signal inputted thereto to thereby generate a damped data signal, wherein a damping resistance of the damping is variable; a variable delay section giving a variable delay to a clock signal to thereby generate a delayed clock signal; a data fetch section fetching data from the damped data signal in synchronization with the delayed clock signal; and a measurement section measuring degree of waveform distortion of the data signal and detecting a data error of the data fetched by the data fetch section.

The present invention provides a semiconductor integrated circuit and an interface circuit configured to select a damping resistance suitable for the actual implementation, thereby reducing EMI.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram illustrating an exemplary configuration of a semiconductor integrated circuit according to the first embodiment of the present invention;

FIG. 2 is a diagram illustrating a method for setting the damping resistance and the clock signal delay;

FIG. 3 is a diagram showing an exemplary configuration of a semiconductor integrated circuit according to the second embodiment of the present invention;

FIG. 4 is a diagram showing an exemplary configuration of a semiconductor integrated circuit according to the third embodiment of the present invention;

FIG. 5 is a diagram for illustrating exemplary waveforms of signals generated within the semiconductor integrated circuit; and

FIG. 6 is a diagram illustrating a procedure for automatically setting the damping resistance and the clock signal delay.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

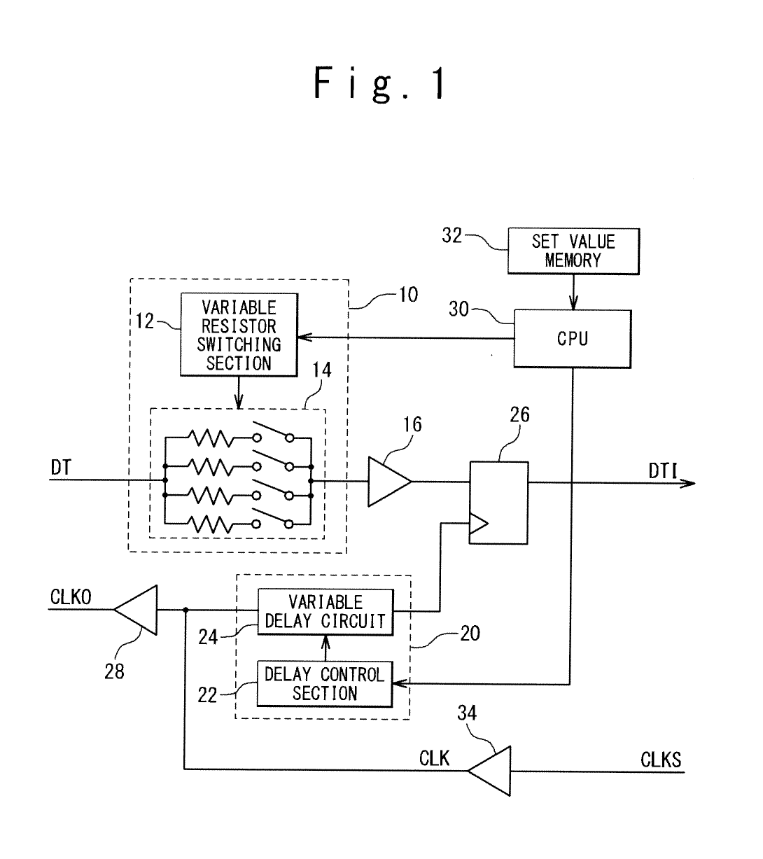

FIG. 1 is a diagram showing an exemplary configuration of an external interface section of a semiconductor integrated circuit of a first embodiment according to the present invention. The semiconductor integrated circuit is provided with a damping resistor section 10, a clock delay section 20, a flipflop 26 used as a data fetch section, a CPU (Central Processing Unit) 30, a set value memory 32, and buffer circuits 16, 28 and 34. The damping resistor section 10 includes a variable resistor switching section 12, and a variable resistor circuit 14, and the clock delay section 20 includes a delay control section 22, and a variable delay circuit 24.

The damping resistor section 10 provides damping to an input data signal DT and supplies the damped data signal to the buffer circuit 16. The damping amount is adjusted by switching the resistance value of the variable resistor circuit 14 with the variable resistor switching section 12 in response to a command received from the CPU 30. The buffer circuit 16 provides waveform recovery to the received data signal and supplies the resultant data signal to the data fetch section 26.

The CPU 30 reads resistance data indicating the resistance to be set to the variable resistor circuit 14 stored in the set value memory 32 and supplies the resistance data to the damping resistor section 10 to control the resistance value of the variable resistor circuit 14. The CPU 30 also reads delay data indicating the delay amount of the variable delay circuit 24 stored in the set value memory 32 and supplies the delay data to the clock delay section 20 to control the delay amount to be given to a clock signal CLK.

In the damping resistor section 10, the variable resistor switching section 12 switches the resistance value of the variable resistor circuit 14 under the control of the CPU 30. The clock signal CLK, which is generated from a clock signal CLKS and distributed to the interface section, is outputted as a clock signal CLKO to an external counterpart apparatus outside of the semiconductor integrated circuit via the buffer circuit 28. The clock signal CLKO is sent to the external counterpart apparatus and also supplied to the clock delay section 20. In the clock delay section 20, the delay control section 22 controls the delay amount to be given to the clock signal CLK in the variable delay circuit 24 under the control of the CPU 30. The variable delay circuit 24 delays the inputted clock signal CLK and supplies the delayed clock signal to the data fetch section 26.

The data fetch section (flipflop) 26 fetches data from the recovered data signal received from the buffer circuit 16 in synchronization with the delayed clock signal, and outputs a signal DTI corresponding to the input data signal, to an internal circuit.

In the following, a description is given of an exemplary operation of the interface section. The interface section supplies the clock signal CLKO to the counterpart apparatus (such as a serial flash memory), and receives the data signal DT outputted from the counterpart apparatus in synchronization with the clock signal.

The clock signal CLKS used in the interface section, which is selected out of clock signals generated in the semiconductor integrated circuit, is supplied to the interface section via the buffer circuit 34 as the clock signal CLK. The clock signal CLK is supplied to the counterpart apparatus via the buffer circuit 28 as the clock signal CLKO, and also supplied to the clock delay section 20.

The data signal DT received from the counterpart apparatus is inputted to the damping resistor section 10. The waveform of the input data signal damped by the damping resistor section 10 is recovered by the buffer circuit 16, and the resultant signal is fed to the data fetch section (flipflop) 26. The resistance data indicating the damping resistance to be set is preliminarily stored in the set value memory 32. The CPU 30 obtains the resistance data indicating the damping resistance from the set value memory 32, for example, immediately after the power-on, in the initialization process, or the like, and sets the resistance data to the variable resistor switching section 12 of the damping resistor section 10. The variable resistor switching section 12 switches the variable resistor circuit 14 to the indicated damping resistance.

The increase in the damping resistance causes distortion of the waveform of the input signal, resulting in the slow rising and falling of the signal. Therefore, the timing at which the input signal is to be fetched is delayed. The clock signal supplied to the data fetch section 26 is delayed with a certain delay amount by the clock delay section 20. This delay amount is adjusted so that the timing delay caused by the damping resistance is compensated. The delay data indicating the delay amount to be set is preliminarily stored in the set value memory 32. The CPU 30 obtains the delay data indicating the delay amount to be set from the set value memory 32, for example, immediately after the power-on, in the initialization process, or the like, and sets the delay data to the delay control section 22 of the clock delay section 20. The delay control section 22 sets the delay amount of the variable delay circuit 24 to the delay amount indicated by the delay data.

In such a way, an interface circuit with reduced noise generation and malfunction can be obtained by controlling the damping resistance in accordance with the state of the circuit to be connected and giving the delay amount in accordance with the damping resistance to the clock signal. That is, a semiconductor integrated circuit with reduced EMI and stable operation can be realized. Although the present invention is applied to an interface circuit configured to supply the clock signal CLK to the counterpart apparatus in this embodiment, the clock signal CLK may be supplied from an external apparatus as a signal indicating the timing of the data signal DT.

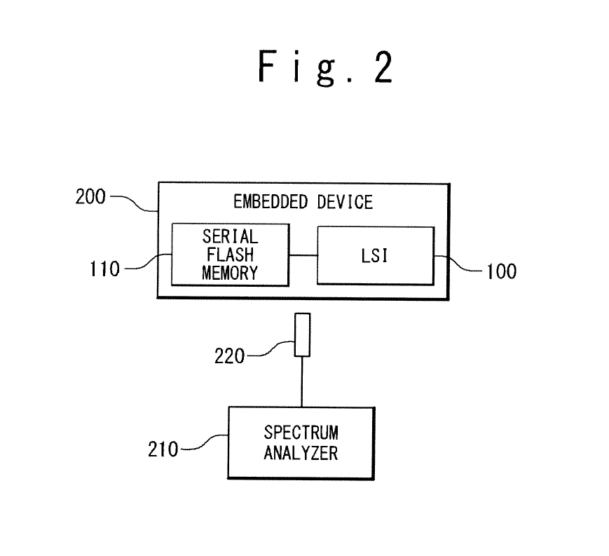

Next, a description is given of a method for setting the damping resistance and the delay amount of the clock signal with reference to FIG. 2.

FIG. 2 shows an exemplary system configuration for performing EMI measurement. Provided is an embedment device 200 including a semiconductor integrated circuit 100 of this embodiment and a serial flash memory 110 which operates as a counterpart apparatus. The clock signal CLKO is supplied from the semiconductor integrated circuit 100 to the serial flash memory 110, and the serial flash memory 110 outputs the data signal DT in synchronization with the clock signal CLKO to the semiconductor integrated circuit 100 through a connection in which no external damping resistance intervenes. Noise containing high-frequency components is radiated from a signal line connected between the semiconductor integrated circuit 100 and the serial flash memory 110. The noise is detected by a high frequency probe 220 and analyzed by a spectrum analyzer 210.

In general, the output of the serial flash memory 110, which is a sort of general-purpose LSIs, has a large drive capability, since the destination of the output signal is not specified. This is one of major causes of the EMI. In order to reduce the EMI, the damping resistor is inserted so that the signal is damped. The semiconductor integrated circuit 100 of this embodiment incorporates the damping resistor therein, and switches the damping resistance of the variable resistor circuit 14 of the damping resistor section 10 so that the EMI is reduced below a desired level. When the damping resistance is determined so as to reduce the EMI below a predetermined value, the resistance data indicating the determined damping resistance is written into the set value memory 32. The resistance data may be directly written into the set value memory 32 with using a dedicated tool, or may be written by the CPU 30.

After the damping resistance is thus determined, the delay amount of the clock signal CLK is determined in accordance with the determined damping resistance. More specifically, the delay amount is determined so that the data signal DT inputted in synchronization with the clock signal CLK can be fetched without a data error. In one embodiment, known data are inputted and checked to determine whether a data error occurs. In an alternative embodiment, data attached with error detection codes may be inputted and checked to determine whether a data error occurs. The delay amount is determined so as to cause a data error, and delay data indicating the determined delay amount is written into the set value memory 32. As is the case of the damping resistance, the determined delay data may be directly written into the set value memory 32 by using a dedicated tool, or may be written by the CPU 30.

### Second Embodiment

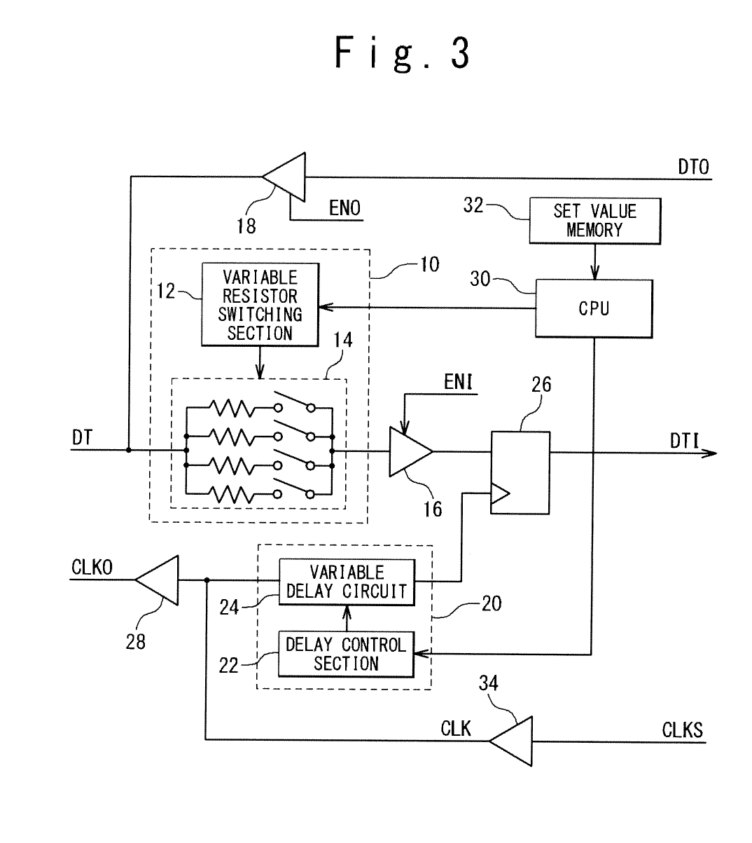

FIG. 3 is a diagram showing an exemplary configuration of an external interface section of a semiconductor integrated circuit of a second embodiment according to the present invention. The semiconductor integrated circuit is provided with a buffer circuit 18, in addition to the damping resistor section 10, the clock delay section 20, the data fetch section 26, the CPU 30, the set value memory 32, and buffer circuits 16, 28 and 34. The interface circuit of the second embodiment exchanges data with a counterpart semiconductor integrated circuit over the data signal DT. That is, in this embodiment, an exemplary configuration of the interface circuit for supporting bidirectional data signaling is given. Specifically, a data signal DTO is outputted to the counterpart semiconductor integrated circuit via the buffer circuit 18 as the data signal DT. The output of the buffer circuit 18 is connected to the outside node of the damping resistor section 10. That is, a signal line which transfers the data signal DT is branched within the semiconductor integrated circuit and connected to both of the output of the buffer circuit 18 and the input of the damping resistor section 10.

The buffer circuit 18 is controlled by an output enable signal ENO, and outputs the data signal DTO as the data signal DT only when the data output is enabled. When the data output is not enabled, the output of the buffer circuit 18 is placed into the high impedance state, so as not to interfere with the data signal DT. The data signal DT received from the counterpart semiconductor integrated circuit is damped by the damping resistor section 10, and the damped data signal is supplied to the data fetch section 26 via the buffer circuit 16. The buffer circuit 16 is controlled in response to an input enable signal ENI to provide waveform recovery, and supplies the recovered data signal DT to the data fetch section 26 only when the data input is enabled. This effectively avoids the data fetch section 26 being influenced by the data signal DT during the data output. Although the clock signal CLKO may be outputted from the counterpart semiconductor integrated circuit, the following description is given for a case where the clock signal CLKO outputted from the present semiconductor integrated circuit, as is the case of the first embodiment. Since other configurations are the same as those of the first embodiment, detailed description thereof will be omitted.

The operation of the interface section in this embodiment is substantially same as that in the first embodiment except for that the interface section is adapted to the data output. In the following, a description is given of the operation of the interface section in which data identifying commands are sent to the counterpart apparatus in synchronization with the clock signal CLKO, and data representative of responses thereto are inputted to the damping resistor section 10 in the form of the data signal DT.

The output data signal DTO, which is generated in synchronization with the clock signal CLK, is outputted as the data signal DT when the buffer circuit 18 is placed into the output enable state in response to the output enable signal ENO. In this operation, the buffer circuit 16 is disenabled in response to the input enable signal ENI so that the output signal is not responsive to the input signal and the change of the data signal DT is not transmitted to the data fetch section 26. The buffer circuit 16 has a high input impedance and can be treated as the open state when viewed from the input side of the damping resistor section 10. That is, the output of the buffer circuit 18 is sent to the counterpart apparatus without suffering from the influence of the damping resistor section 10. When the data output is completed, the buffer circuit 18 places the output node thereof into the high impedance state in response to the output enable signal ENO, so as to eliminate the influence on the data signal DT.

When the counterpart apparatus sends the data signal DT in synchronization with the clock signal CLKO, the waveform of the signal damped by the damping resistor section 10 is recovered by the buffer circuit 16 in the interface section, and the recovered signal is fetched by the data fetch section 26. The reflection of the inputted data signal DT is decreased by the damping resistor section 10, which results in the reduction of the EMI.

The resistance data indicating the suitable resistance value of the damping resistor is preliminarily stored in the set value memory 32. The CPU 30 obtains the resistance data indicating the damping resistance from the set value memory 32, for example, immediately after the power-on, in the initialization process, or the like, and sets the resistance data to the variable resistor switching section 12 of the damping resistor section 10. The variable resistor switching section 12 switches the variable resistor circuit 14 to the indicated damping resistance.

The increase in the damping resistance causes waveform distortion of the input signal, resulting in the slow rising and falling of the signal. Therefore, the timing at which the input signal is to be fetched is delayed. The clock signal supplied to the data fetch section 26 is delayed by a desired delay amount by the clock delay section 20. This delay amount is adjusted so that the timing delay caused by the damping resistance is compensated. The delay data indicating the desired delay amount is preliminarily stored in the set value memory 32. The CPU 30 obtains the delay information indicating the delay amount from the set value memory 32, for example, immediately after the power-on, in the initialization process, or the like, and sets the delay data to the delay control section 22 of the clock delay section 20. The delay control section 22 sets the delay amount of the variable delay circuit 24 to the indicated delay amount. The damping resistance and the delay amount of the clock signal may be set in the same way as the method described in the first embodiment.

As thus discussed, for a case where the signal line is used for both of the data input and data output, the incorporation of the damping resistor section 10 into the semiconductor integrated circuit allows the damping resistor section 10 to be arranged between the internal circuit and the branching point of the input signal line and output signal line. This effectively suppresses the influence of the damping resistor section 10 on the output data signal.

### Third Embodiment

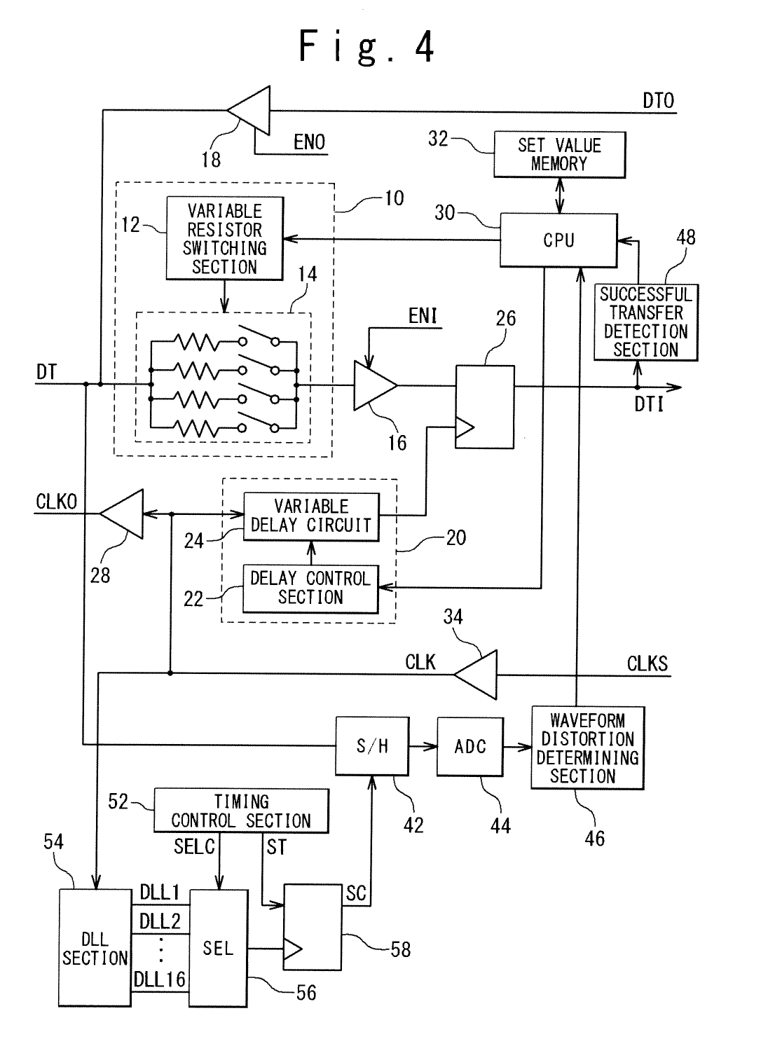

FIG. 4 is a diagram showing an exemplary configuration of an external interface section of a semiconductor integrated circuit of a third embodiment according to the present invention. The semiconductor integrated circuit of this embodiment additionally includes a sample-and-hold circuit (S/H) 42, an analog/digital conversion circuit (ADC) 44, a waveform distortion determining section 46, a successful transfer detection section 48, a timing control section 52, a DLL (Delay Locked Loop) section 54, a selection circuit (SEL) 56, and a clock output circuit (flipflop) 58 in addition to the circuit components of the semiconductor integrated circuit of the second embodiment. The additional circuit components are used for determining the optimal damping resistance of the variable resistor circuit 14 and the optimal delay amount of the clock signal for the determined damping resistance.

The inputted data signal DT is damped by the damping resistor section 10, and the damped data signal is fed to the buffer circuit 16. The buffer circuit 16 provides waveform recovery to the damped data signal and supplies the resultant data signal to the data fetch section 26. The data fetch section 26 fetches data from the recovered data signal received from the buffer circuit 16. The successful transfer detection section 48 determines whether or not the fetched data are correct data. The determination result is sent to the CPU 30.

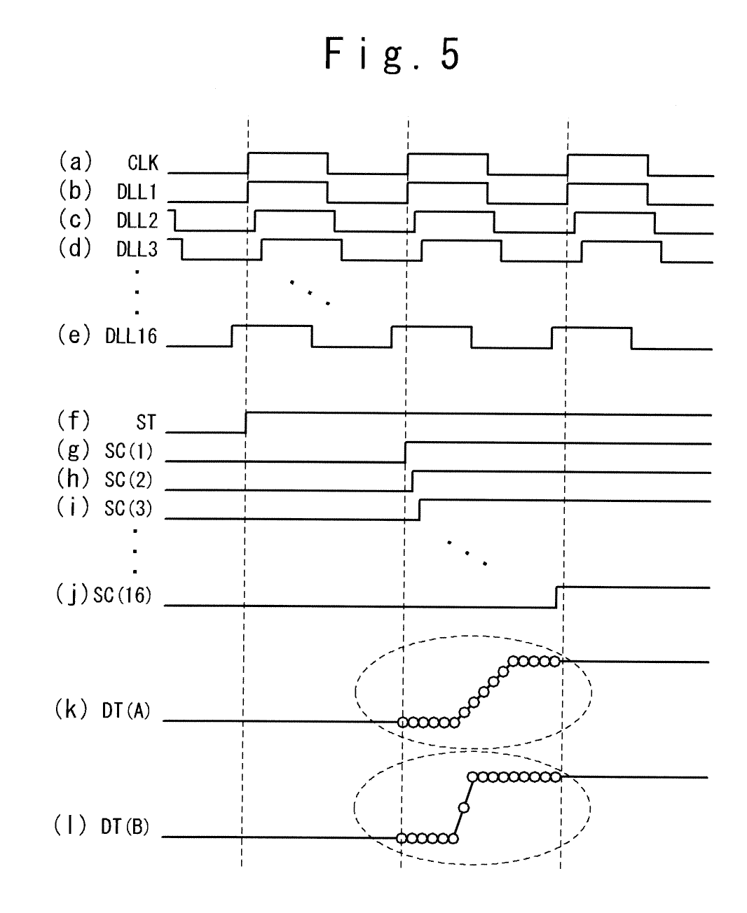

The DLL section 54 generates a set of sampling clock signals DLL1 to DLL16 ((b) to (e) of FIG. 5) having different phases from the clock signal CLK ((a) in FIG. 5). The generated sampling clock signals include: the clock signal DLL1 of the same phase as the clock signal CLK; the clock signal DDL2 of a phase 1/16-cycle lagging from the clock signal CLK; the clock signal DDL3 of a phase 2/16-cycle lagging from the clock signal CLK; . . . ; and the clock signal DDL16 of a phase 15/16-cycle lagging from the clock signal CLK.

The timing control section 52 supplies a selection signal SELC for selecting one of the sampling clock signals DLL1 to DLL16 to the selection circuit 56, and supplies a sampling trigger signal ST ((f) in FIG. 5) indicating start of sampling of the input signal to the clock output circuit (flipflop) 58. The selection circuit 56 selects one of the clock signals DLL1 to DLL16 in response to the selection signal SELC outputted by the timing control section 52, and outputs the selected clock signal to the clock output circuit 58. The clock output circuit 58 latches the sampling trigger signal ST outputted by the timing control section 52 in synchronization with the selected clock signal outputted by the selection circuit 56, and thereby generates a sampling clock signal SC indicating the sample-and-hold timing to the sample-and-hold circuit 42 ((g) to (j) of FIG. 5).

The sample-and-hold circuit 42 samples and holds the input signal DT in synchronization with the sampling clock signal SC, and outputs the sampled input signal to the analog/digital conversion circuit 44. The analog/digital conversion circuit 44 provides analog-digital conversion to the analog input signal held by the sample-and-hold circuit 42, to generate a digital input signal. The digital input signal is fed to the waveform distortion determining section 46. One set of sampling data are obtained in response to each pull-up of the sampling trigger signal ST. The waveform of the input signal DT in one cycle of the clock signal CLK is obtained by performing 16 samplings at different timings by the sample-and-hold circuit 42 as shown in (k) and (l) of FIG. 5.

The waveform distortion determining section 46 determines the degree of waveform distortion on the basis of the sampling data indicating the waveform of the input signal, and outputs result data indicating the degree of waveform distortion to the CPU 30. In one example, as shown in (k) of FIG. 5, the sampling data of the waveform of the data signal DT (A) include: six pieces data of the minimum value (value “0”), data of values of “⅙”, “ 2/6”, “ 3/6”, “ 4/6”, “⅚”, and five pieces of data of the maximum value (value “1”). In another example, as shown in (l) of FIG. 5, the sampling data of the waveform of the data signal DT (B) include: six pieces of data of the minimum value (value “0”), data of a value of 3/6, and nine pieces of data of the maximum value (value “1”). The waveform distortion determining section 46 determines that the input signal is subjected to distortion of a predetermined degree, when the number of the sampling data of the intermediate values found between the sampling data of the minimum and maximum values satisfies a predetermined condition.

The CPU 30 determines whether the damping resistance works effectively on the basis of the determination result of the degree of the waveform distortion. The CPU 30 reduces the damping resistance when the effect of the damping resistance is excessive, and increases the damping resistance when the effect is insufficient, so that the damping resistance is set to work effectively.

Next, a description is given of a procedure for automatically setting the damping resistance of the damping resistor section 10 and the delay amount of the clock delay section 20.

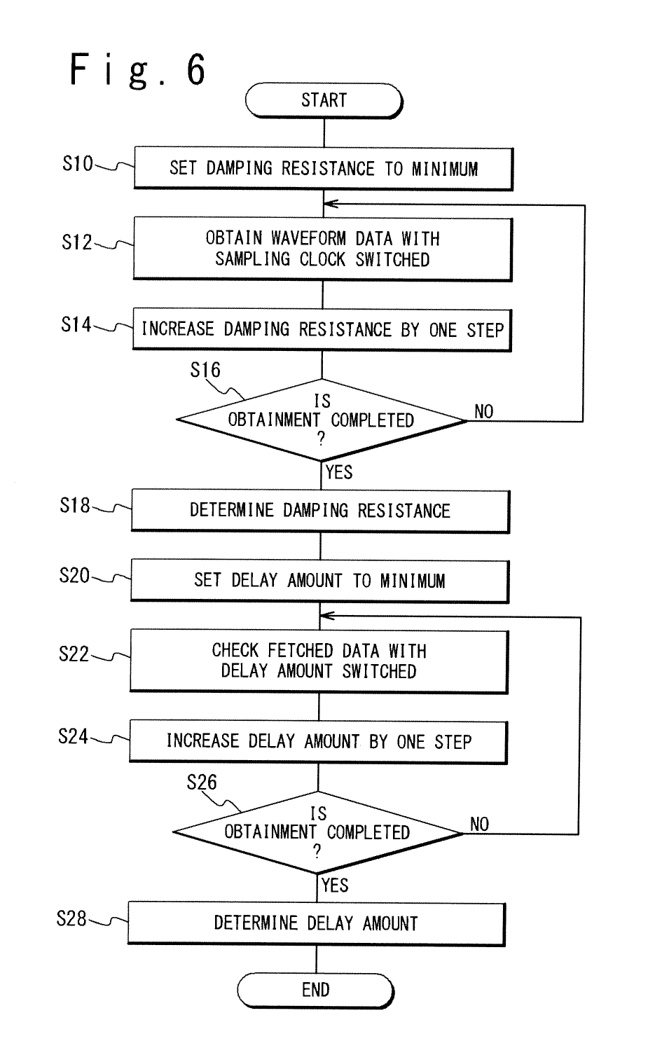

In one embodiment, the automatic setting operation may be performed for setting the damping resistance and the clock delay amount suitable for a system including the semiconductor integrated circuit of the present embodiment, when the system is tested or adjusted. The operation may be performed immediately after the power-on or in the initialization process. FIG. 6 is a flowchart showing an exemplary procedure for automatically setting the resistance value and the delay amount.

The CPU 30 sets the damping resistance of the variable resistor circuit 14 of the damping resistor section 30 to minimum at Step S10. A measurement is started in the initial state in which the damping effect is weak.

Waveform data of the input signal are obtained while the phase of the sampling clock signal SC is switched to be supplied to the sample-and-hold circuit 42 at Step S12. In this embodiment, the waveform of the input signal is indicated by 16 pieces of data as shown in (k) and (l) of FIG. 5, since the sampling clock signal SC is synchronized with the selected one of the sampling clock signals DLL1 to DLL16.

After a complete set of 16 waveform data for one resistance value are obtained, the damping resistance of the variable resistor circuit 14 is increased by one step at Step S14. The procedure returns to Step S12, and such measurement is performed for all the allowed resistance values which can be set to the variable resistor circuit 14 (Step S16-NO).

The waveform distortion determining section 46 determines the degree of the waveform distortion on the basis of the obtained data indicating the waveform of the input signal, and outputs the result thereof to the CPU 30. Let us consider a case, for example, where measured waveform data of the data signal DT (A) for a certain damping resistance include: six pieces of data of the minimum value (value “0”); data of values of ⅙, 2/6, 3/6, 4/6, ⅚; and five pieces of data of the maximum value (value “1”) as shown in (k) of FIG. 5, and measured waveform data of the data signal DT (B) for another damping resistance include: six pieces of data of the minimum value (value “0”); data of values of 3/6; and nine pieces of data of the maximum value (value “1”) as shown in (l) of FIG. 5. In this case, the waveform distortion determining section 46 determines that the input signal is subjected to distortion of a predetermined degree, when the number of the pieces of data of the intermediate values found between the data of the minimum value and the maximum value is in a predetermined range. In a case where the predetermined range is from three to six, the waveform shown in (k) of FIG. 5 is determined to be more appropriate out of the two waveforms.

After the measurement is completed for all the allowed damping resistance values (Step S16-YES) and thereby the data indicating the degrees of the waveform distortions are accumulated, the CPU 30 selects one of the allowed damping resistances so that the selected damping resistance provides an optimal waveform at Step S18. The resistance data indicating the selected damping resistance value is stored in the set value memory 32.

Successively, a procedure for determining the delay amount to be given to the clock signal CLK is started. Firstly, the CPU 30 sets the delay amount of the variable delay circuit 24 to minimum at Step S20.

The data fetch section 26 fetches reception data from the data signal DT with the damping resistance selected at Step S18 and the delay amount set at Step S20. The successful transfer detection section 48 checks the reception data at Step S22. That is, the successful transfer detection section 48 compares expected data and the actually-fetched reception data to thereby detect occurrence of a data error. Alternatively, the successful transfer detection section 48 may verify an error detection code attached with the reception data to thereby detect occurrence of a data error.

After the check of the reception data, the CPU 30 controls the delay control section 22 to increase the delay amount of the variable delay circuit 24 by one step at Step S24. The procedure returns to Step S22, and such data error detection is performed for all the allowed delay amounts which can be set to the variable delay circuit 24 (Step S26-NO).

When the data error detection is completed for all the allowed delay amounts (Step S26-YES), the CPU 30 determines the optimal delay amount of the variable delay circuit 24 on the basis of the detected reception data error at Step S28. In a case where there is a plurality of delay amounts with which no reception data error occurs, the center value thereof may be preferably selected. However, in order to suppress the delay amount as far as possible, the minimum delay amount or a delay value which is several steps larger than the minimum delay value may be selected among the delay values with which no the reception data error occurs. The delay data indicating the determined delay amount is stored in the set value memory 32.

After the resistance value of the variable resistor circuit 14 and the delay value of the variable delay circuit 24 are determined in this way and stored into the set value memory 32, the resistance value and delay amount stored in the set value memory 32 as the optimal values for the system are set to the variable resistor circuit 14 and the variable delay circuit 24 immediately after the power-on, in the initialization process, or the like, so that an interface circuit is provided which effectively suppresses the EMI with a reduced number of data transfer errors.

In the above-described procedure, the resistance value of the variable resistor circuit 14 and the delay amount of the variable delay circuit 24 are initially set to minimum and then gradually increased to determine the optimal values; however, in a case where optimal values can be roughly predicted, the above-described procedure is performed for only for values in the vicinity of the predicted optimal values in determining the actual optimal values. Also, although the input of the sample-and-hold circuit (S/H) 42 is connected to the input of the variable resistor circuit 14 in FIG. 4, the input of the sample-and-hold circuit (S/H) 42 may be connected to the output of the variable resistor circuit 14.

Although the present invention is described above with reference to the embodiments, the present invention is not limited to the above embodiments; the present invention may be implemented in the form of any combination of the above-described embodiments as long as there is no inconsistency. The actual implementation of the present invention may be variously modified within the scope of the present invention which can be understood by those who skilled in the art.

What is claimed is:

1. A semiconductor integrated circuit, comprising:
a variable resistor section providing damping to a data signal inputted thereto to thereby generate a damped data signal, wherein a damping resistance of the damping is variable;
a variable delay section giving a variable delay to a clock signal to thereby generate a delayed clock signal; and
a data fetch section fetching data from said damped data signal in synchronization with said delayed clock signal.

2. The semiconductor integrated circuit according to claim 1, wherein said variable resistor section includes:
a variable resistor circuit having a resistance varied in response to a switching signal; and
a variable resistor switching section outputting said switching signal in response to an instruction.

3. The semiconductor integrated circuit according to claim 1, wherein said variable delay section includes:
a variable delay circuit having a delay varied in response to a delay control signal; and
a delay control section outputting said delay control signal in response to an instruction.

4. The semiconductor integrated circuit according to claim 1, further comprising:
a setting value memory section storing resistance data indicating the damping resistance to be set to said variable resistor section and delay data indicating the delay to be set to said variable delay section; and
a control section obtaining said resistance data and said delay data,
wherein said control section sets the damping resistance to said variable resistor section in response to said resistance data and sets the delay to said variable delay section in response to said delay data.

5. The semiconductor integrated circuit according to claim 1, further comprising:
a signal line receiving said data signal; and
a data output circuit outputting data onto said signal line,
wherein an output node of said data output circuit is connected to said signal line at a branching point within said semiconductor integrated circuit.

6. The semiconductor integrated circuit according to claim 1, further comprising: a measurement section measuring degree of waveform distortion of said data signal and detecting a data error of said data fetched by said data fetch section,
wherein the damping resistance of said variable resistor section and the delay of said variable delay section are automatically set in response to said measured degree of waveform distortion and said detected data error.

7. The semiconductor integrated circuit according to claim 1, further comprising: a buffer circuit externally outputting said clock signal,
wherein said data signal is outputted from a counterpart apparatus in synchronization with said outputted clock signal.

8. An interface circuit, comprising:
a variable resistor section providing damping to a data signal inputted thereto to thereby generate a damped data signal, wherein a damping resistance of the damping is variable;
a variable delay section giving a variable delay to a clock signal to thereby generate a delayed clock signal;
a data fetch section fetching data from said damped data signal in synchronization with said delayed clock signal; and
a measurement section measuring degree of waveform distortion of said data signal and detecting a data error of said data fetched by said data fetch section.

9. The interface circuit according to claim 8, further comprising:
a setting value storage section storing resistance data indicating the damping resistance to be set to said variable resistor section and delay data indicating the delay to be set to said variable delay section; and
a control section obtaining said resistance data and said delay data,
wherein said control section sets the damping resistance to said variable resistor section in response to said resistance data and sets the delay to said variable delay section in response to said delay data.

10. The interface circuit according to claim 8, further comprising:
a signal line receiving said data signal; and
a data output circuit outputting data onto said signal line,
wherein an output node of said data output circuit is connected to said signal line at a branching point within said semiconductor integrated circuit.

11. The interface circuit according to claim 8, further comprising: a buffer circuit externally outputting said clock signal,
wherein said data signal is outputted from a counterpart apparatus in synchronization with said outputted clock signal.

12. An interface system, comprising:
a semiconductor integrated circuit; and
a counterpart apparatus outputting a data signal,
wherein said semiconductor integrated circuit comprises:
a variable resistor section providing damping for said data signal inputted thereto to thereby generate a damped data signal, wherein a damping resistance of the damping is variable;
a variable delay section giving a variable delay to a clock signal synchronized with an input timing of said data signal, to thereby generate a delayed clock signal;
a data fetch section fetching data from said damped data signal at a timing indicated by said delayed clock signal, and
wherein said data signal outputted from said counterpart apparatus is inputted to said semiconductor integrated circuit through a connection in which no damping resistor intervenes.

13. The interface system according to claim 12, wherein a drive capability of a circuit outputting said data signal integrated within said counterpart apparatus is larger than that of a circuit generating a signal within said semiconductor integrated circuit.

14. The interface system according to claim 12, wherein said semiconductor integrated circuit is configured to receive a signal from said counterpart apparatus and to set the damping resistance of said variable resistor section and the delay of said variable delay section, in response to said signal received from said counterpart apparatus.
